(19) United States
(12) Patent Application Publication
(10) Pub. No.: US 2013/0136896 A1
(43) Pub. Date: May 30, 2013

(54) METHOD FOR PRODUCING COATING LAYER WITH LOW-FRICTION

(71) Applicants: In Woong Lyo, Suwon (KR); Woong Pyo Hong, Yongin (KR); Kwang Hoon Choi, Hwaseong (KR); Hyuk Kang, Hwaseong (KR)

(72) Inventors: In Woong Lyo, Suwon (KR); Woong Pyo Hong, Yongin (KR); Kwang Hoon Choi, Hwaseong (KR); Hyuk Kang, Hwaseong (KR)

(73) Assignee: HYUNDAI MOTOR COMPANY, Seoul (KR)

(21) Appl. No.: 13/483,484

(22) Filed: May 30, 2012

(30) Foreign Application Priority Data
Nov. 25, 2011 (KR) 10-2011-0124270

(51) Int. Cl. C23C 14/34; B32B 3/10

(52) U.S. Cl. 428/143; 204/192.15

(57) ABSTRACT

In a method for producing a coating layer using plasma which includes heating, buffer layer coating, coating and cooling, a method for producing a coating layer with low-friction comprises: a coating step of forming TiAgN coating layer on the surface of a base material using Ti arc source and Ag sputtering source at a certain coating temperature; a fraction increase step of increasing the Ag fraction on the surface by increasing bias voltage and sputtering power for a certain time period; and a nano-forming step of forming Ag nanoparticles on the surface by maintaining the temperature at 50˜100° C. higher than the certain coating temperature for a certain time period.

### CROSS-REFERENCE TO RELATED APPLICATION

This application claims under 35 U.S.C. §119(a) the benefit of Korean Patent Application No. 10-2011-0124270 filed on Nov. 25, 2011, the entire contents of which are incorporated herein by reference.

### BACKGROUND

(a) Technical Field

The present disclosure relates to a method for producing a coating layer having low-friction, and more particularly to a method which forms nano-sized Ag particles on a surface by controlling processing conditions (bias voltage, sputter power and the like) to form the coating layer.

(b) Background Art

Typically, a plasma coating technique is used to coat a material on an untreated base material using plasma phenomenon under vacuum condition. Such coatings can add mechanical and functional characteristics that an original base material does not have. Plasma coating techniques are commonly divided to CVD (Chemical vapor deposition) and PVD (Physical vapor deposition).

As PVD techniques, vacuum deposition, sputtering, ion plating and the like are being broadly used. Ion plating is further classified into various coating methods according to the plasma activation method and coating material ionization methods.

One type of ion plating technique is arc ion plating, in which a coating material (target) is vapor ionized as a negative electrode using arc discharge. Arc ion plating is useful for the formation of hard coatings because it has a rapid evaporation rate which leads to rapid coating and, thus, good productivity, as well as high ionization, crash and migration energies.

A DLC (Diamond Like Carbon) coating is a type of low-friction coating that has been mainly used to coat conventional vehicle components. While DLC coatings are advantageously already mass-produced and have been broadly used, it has insufficient friction characteristic at both high and low temperature and low abrasion resistance. Further, it also has a relatively long friction stable section, which is problematic.

TiN coating materials have excellent heat resistant and wear resistant properties. However, due to insufficient low-friction properties, its application to various drive components is limited. Accordingly, to obtain the necessary low-friction property, a composite coating layer is formed using a soft metal such as Ag. However, the initial low-friction property is still limited and, further, it is difficult to carefully control the Ag fraction as needed.

The present invention relates to a coating method that provides the desired low-friction property and significantly reduces the running-in time after molding. In particular, the present invention relates to a method for forming nano-sized Ag particles on a surface by controlling processing conditions (bias voltage, sputter power and the like) to form a coating layer, so as to improve the low-friction property of the surface.

The information disclosed in this Background of the Invention section is only for enhancement of understanding of the general background of the invention and should not be taken as an acknowledgement or any form of suggestion that this information forms the prior art already known to a person skilled in the art.

### SUMMARY OF THE DISCLOSURE

The present invention has been made in an effort to solve the above-described problems associated with prior art. It is an object of the present invention to provide a method for producing a coating layer with low-friction, and, in particular, a method which forms nano-sized Ag particles on a surface by controlling processing conditions (bias voltage, sputter power and the like) to form the coating layer. The present methods provide a coating layer having a superior low-friction property as compared to a conventional coating layer.

The base material can be any material on which a coating layer may be provided so as to improve the low-friction property. According to various aspects, the present methods provide a coating layer on a vehicle component, such as engine and drive components and, thus, the coating layer may be formed on any base material which forms such vehicle components.

In one aspect, the present invention provides a method to produce a coating layer using plasma which includes heating, buffer layer coating, coating (i.e. low-friction layer coating) and cooling.

According to various embodiments, the low-friction layer coating step comprises: a coating step of forming a TiAgN coating layer on the surface of a base material using a Ti arc source and an Ag sputtering source carried out within a suitable temperature range (“coating temperature”); a fraction increase step of increasing the Ag fraction on the surface layer by increasing bias voltage and sputtering power for a suitable time period; and a nano-forming step of forming Ag nanoparticles on the surface by maintaining the temperature at a suitable temperature which higher than the coating temperature, for a suitable time period.

According to various embodiments, the fraction increase step is carried out for 3˜7 min so as to increase the bias voltage and sputtering power.

According to various embodiments, he nano-forming step is carried out at about 50˜100° C. higher temperature than the coating temperature. According to various embodiments, this coating temperature is about 250˜350° C. and the coating step is carried out for about 10˜20 min.

After the nano-forming step, a cooling step may be carried out, wherein the temperature is reduced to a suitable temperature, such as room temperature. This cooling step can be carried out in a chamber. According to various embodiments, a single chamber can be used to carry out multiple, and even all steps (i.e. heating, buffer layer coating, coating and cooling), of the method. However, it is also possible to provide multiple chambers for different steps, if desired.

According to various embodiments, the heating step comprises making the temperature distribution within the chamber uniform by maintaining the condition in the chamber at a temperature of about 300° C. or more for about 40 min or more.

After the heating step, a buffer layer coating step may be carried out. According to an embodiment, the buffer layer coating step comprises depositing a Ti coating layer on the surface of the base material by a Ti arc source.

### BRIEF DESCRIPTION OF THE DRAWINGS

The above and other features of the present invention will now be described in detail with reference to certain exemplary embodiments thereof illustrated the accompanying drawings which are given hereinbelow by way of illustration only, and thus are not limitative of the present invention, and wherein:

FIG. 1 is a configuration diagram of a coating device to conduct the method for producing a coating layer with low-friction according to one embodiment of the present invention;

FIG. 2a is a photo showing the microstructure of a TiAgN coating layer according to a comparative example, and FIG. 2b is a photo showing the microstructure of a TiAgN coating layer coated according to the present invention;

FIG. 3 is a friction coefficient graph at the room temperature and at a high temperature (400° C.) of a TiAgN coating layer according to a comparative example and a TiAgN coating layer coated according to the present invention; and

FIG. 4 is a graph representing running-in time of a TiAgN coating layer according to a comparative example and a TiAgN coating layer coated according to the present invention.

It should be understood that the appended drawings are not necessarily to scale, presenting a somewhat simplified representation of various preferred features illustrative of the basic principles of the invention.

In the figures, reference numbers refer to the same or equivalent parts of the present invention throughout the several figures of the drawing.

### DETAILED DESCRIPTION

Hereinafter, a method for producing a coating layer with low-friction according to the preferred embodiments of the present invention now will be described in detail with reference to the accompanying drawings.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

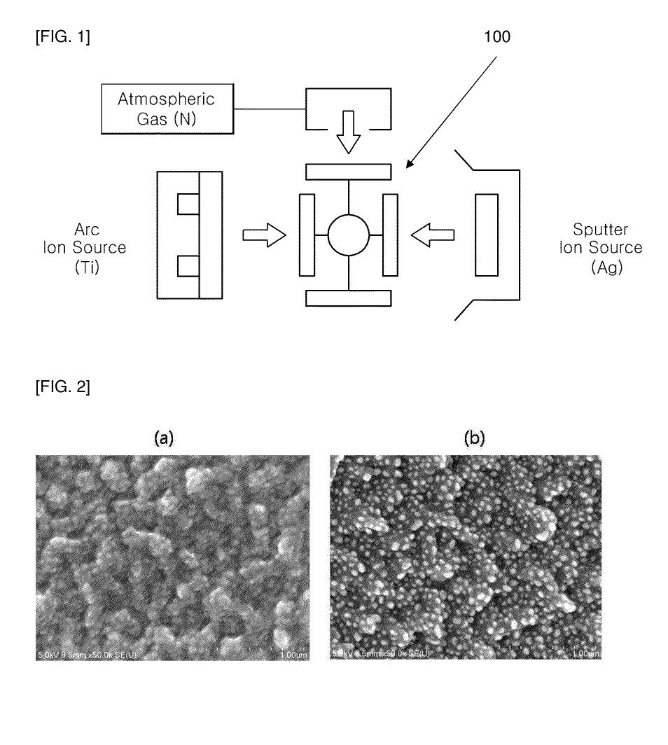

FIG. 1 is a configuration diagram of a coating device to conduct the method for producing a coating layer with low-friction according to one embodiment of the present invention. In particular, the method for low-friction coating according to an embodiment mainly comprises heating, buffer layer coating, coating and cooling using the said device.

In the heating step, the condition in the chamber is maintained at a suitable heightened temperature, such as a temperature of about 300° C. or more for about 40 min or more, so as to provide a uniform temperature distribution. Namely, the temperature in the chamber is maintained at about 300° C. or more so as to smoothly progress the reaction of N (nitrogen), an element fulfilling the heat-resistance, and the heating holding time is set to about 40 min or more so as to make the provide uniform temperature distributions on the surface and interior of the test sample to be coat.

Next, the test sample is cleaned in a cleaning step to remove impurities, thereby improving the adhesion property between the buffer coating layer and the base material. According to various embodiments, the cleaning step can be carried out with ethanol and acetone, using an ion gun for a suitable time, such as 20 min or more.

After cleaning, a Ti buffer layer coating step is carried out using an arc ion source to provide a functional coating layer that improves the adhesion property of the TiAgN layer which is subsequently coated on the base material of the test sample by applying high bias voltage.

According to various embodiments, TiAgN coating (i.e. low-friction layer coating) is conducted at about 250˜350° C. by activating two ion sources of Ti and Ag. According to an exemplary embodiment, the thickness of the TiAgN coating is preferably 2 μm or less. According to a conventional coating method (which is hereafter sometimes referred to as a comparative example and is referred to in FIGS. 2-4), the coating is completed through a cooling step carried out right after the coating step. On the other hand, according to the present invention, after the coating step the following fraction increase step and nano-forming step are conducted to outstandingly improve the low-friction property.

In particular, according to various embodiments the coating method is a method for producing a coating layer using plasma, and it comprises: a coating step of forming TiAgN coating layer on the surface of a base material using a Ti arc source and an Ag sputtering source at a certain temperature; a fraction increase step of increasing the Ag fraction on the surface layer by increasing bias voltage and sputtering power for a certain time period; and a nano-forming step of forming Ag nanoparticles on the surface by maintaining the temperature at a certain temperature which is higher than the temperature of the coating step, for a certain time period.

In the fraction increase step, the Ag fraction of the top-surface layer is improved by increasing the bias voltage and sputtering power during a final portion (e.g. a final 5 min, 4.5 min, 4 min, 3.5 min, 5.5 min, 6 min, etc. or other suitable final portion) of the coating process. Further, after completing the coating process, the temperature of the coating process is increased by about 50˜100° C. more than the temperature of the coating step (e.g. wherein the temperature of the coating step may be about 250˜350° C.) and the increased temperature is maintained for a suitable time (e.g. about 10˜20 min) to form the Ag nanoparticles on the surface.

According to various embodiments, the fraction increase step is preferably carried out so as to increase the bias voltage and sputtering power for about 3˜7 min, and the nano-forming step is maintained at a temperature of about 300˜450° C. for about 10˜20 min.

After the nano-forming step, the method may further comprise a cooling step of cooling the coated base material to room temperature. The cooling step can be carried out in a chamber such as, for example, the same chamber that one or more of the previous steps are carried out in, or in a separate chamber.

According to various embodiments, the coating method of the present invention may further comprise, prior to the low-friction coating layer step, a heating step of making temperature distribution uniform by maintaining the condition in the chamber at a temperature of about 300° C. or more for about 40 min or more. Further, after the heating step and prior to the low-friction coating layer step, the method may further comprise a buffer layer coating step of depositing a Ti coating layer on the surface of the base material by a Ti arc source.

FIG. 2 shows microstructure pictures of a TiAgN coating layer according to a comparative example and a TiAgN coating layer coated according to the present invention, wherein (a) is a picture of the coating surface of the comparative example, which was formed without conducting the fraction increase step and nano-forming step, and (b) is a picture of the coating layer surface of the present invention, which was formed by the present method including the fraction increase step and nano-forming step. As demonstrated, there are clearly more Ag nanoparticles in the coating of the present invention, and therefore, the low-friction property is improved by such a coating.

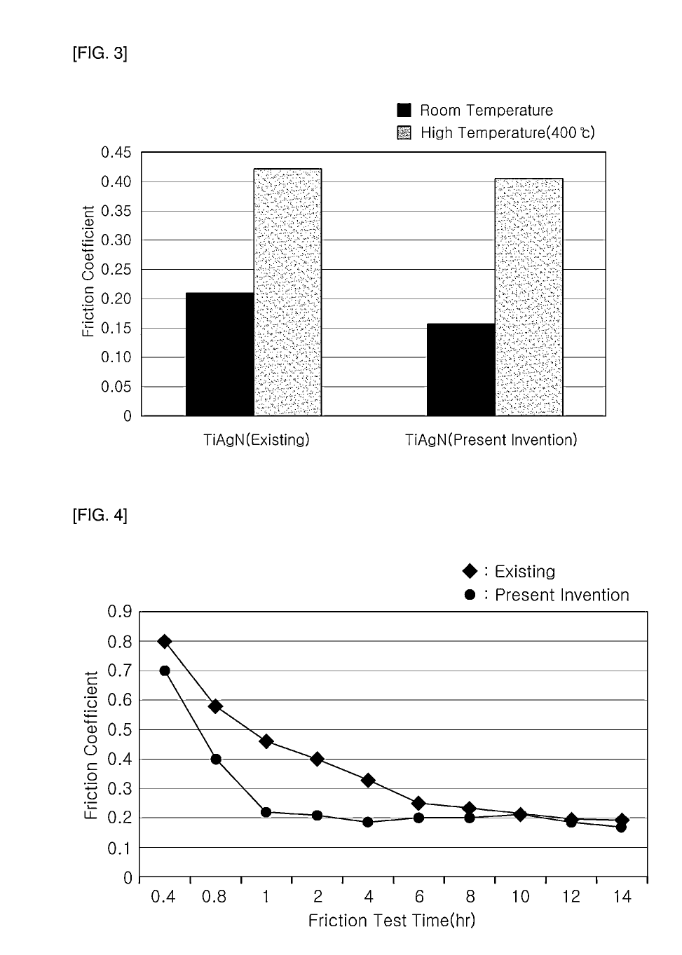

FIG. 3 is a friction coefficient graph at room temperature and high temperature (400° C.) of a TiAgN coating layer coated according to a comparative example and a TiAgN coating layer coated according to the present invention. As shown by the graph, it is confirmed that the present invention improved the fiction property at room temperature by 25% or more as compared to the comparative example (“existing TiAgN”).

Further, FIG. 4 is a graph representing running-in time of a TiAgN coating layer coated according to a comparative example and a TiAgN coating layer coated according to the present invention. As demonstrated by FIG. 4, the present invention reduced the running-in time (friction test time) 8 times or more than the comparative example.

According to the present method for producing a coating layer with low-friction, the low-friction property provided by the surface Ag nanoparticles can be improved without a big change in the existing TiAgN coating production process. Further, the present method makes possible to significantly reduce the running-in time due to the formation of the Ag nanoparticles on the surface.

While the invention will be described in conjunction with exemplary embodiments, it will be understood that present description is not intended to limit the invention to those exemplary embodiments. On the contrary, the invention is intended to cover not only the exemplary embodiments, but also various alternatives, modifications, equivalents and other embodiments, which may be included within the spirit and scope of the invention as defined by the appended claims.

What is claimed is:

1. In a method for producing a low-friction coating layer on the surface of a base material using plasma which comprises:
a low-friction coating layer step of forming a TiAgN coating layer on the surface of the base material using a Ti arc source and an Ag sputtering source at a certain coating temperature, the low-friction coating layer step further including
a fraction increase step of increasing an Ag fraction on the surface by increasing a bias voltage and sputtering power for a certain time period, and
a nano-forming step of forming Ag nanoparticles on the surface by maintaining a temperature at a certain temperature higher than the coating temperature for a certain time period.

2. The method of claim 1, wherein in the coating step, the coating temperature is about 250˜350° C.

3. The method of claim 1, wherein in the fraction increase step, the bias voltage and sputtering power are increased for about 3˜7 min.

4. The method of claim 1, wherein in the nano-forming step, the temperature is maintained at about 50˜100° C. higher than the coating temperature for about 10˜20 min.

5. The method of claim 1, further comprising, after the nano-forming step, a cooling step of cooling to room temperature.

6. The method of claim 1, which further comprises, prior to the low-friction coating layer step, a heating step of maintaining a temperature of about 300° C. or more for about 40 min or more.

7. The method of claim 6, further comprising, after the heating step, a buffer layer coating step of depositing a Ti coating layer on the surface of the base material by a Ti arc source.

8. A low-friction coating layer produced in accordance with the method of claim 1.

9. A vehicle component comprising a base material coated with the low-friction coating layer of claim 8.
